(19) United States
(12) Patent Application Publication
(10) Pub. No.: US 2015/0016067 A1
(43) Pub. Date: Jan. 15, 2015

(54) HIGH FREQUENCY MODULE AND MANUFACTURING METHOD THEREOF

(71) Applicant: Samsung Electro-Mechanics Co., Ltd., Suwon (KR)

(72) Inventors: Chang Sup SONG, Suwon (KR); Jong Pil Park, Suwon (KR)

(21) Appl. No.: 14/325,752

(22) Filed: Jul. 8, 2014

(30) Foreign Application Priority Data
Jul. 9, 2013 (KR) 10-2013-0080388

(51) Int. Cl. H05K 9/00; H05K 3/36; H05K 3/30; H05K 7/06

(52) U.S. Cl. CPC H05K 9/00; H05K 7/06; H05K 3/36; H05K 3/30
USPC 361/736; 29/830

(57) ABSTRACT

A high frequency (HF) module and a manufacturing method thereof. The HF module has a single airtight box-like structure formed by a first PCB, a second PCB, and a third PCB. On a lower surface of the third PCB facing the first PCB, a second electronic component is mounted at a position corresponding to a first electronic component relatively low in height, among first electronic components mounted on the first PCB. Upper and lower ends of a plurality of vias formed within the second PCB are connected to a copper layer existing within a body of the third PCB and a copper layer existing within a body of the first PCB to constitute a single electromagnetic wave shielding unit overall.

### CROSS REFERENCE(S) TO RELATED APPLICATIONS

This application claims the benefit under 35 U.S.C. Section 119 of Korean Patent Application Serial No. 10-2013-0080388, entitled “High Frequency Module and Manufacturing Method Thereof” filed on Jul. 9, 2013, which is hereby incorporated by reference in its entirety into this application.

### BACKGROUND OF THE INVENTION

1. Technical Field

The present invention relates to a high frequency (HF) module employed in mobile devices, or the like, and a manufacturing method thereof.

2. Description of the Related Art

Recently, mobile products such as smartphones, and the like, have been increasingly reduced in size and thickness. In such an environment, a high frequency (HF) module such as WiFi/Bluetooth (BT) may be marketably competitive when it is smaller and thinner. Also, an HF module is required to provide a maximum level of electromagnetic wave shielding.

As a mounting space of an HF module such as WiFi/BT is gradually reduced in mobile products such as smartphones, and the like, and thicknesses of mobile products become thinner, an HF module is required to be thinner. Also, as regulations for various electromagnetic waves are toughened, electromagnetic wave shielding has become an important matter.

A related art HF module has a structure in which an electronic component is mounted on a printed circuit board (PCB) and covered by a metal can for the purpose of electromagnetic wave shielding. In this structure, however, the electronic component and the metal can should be sufficiently separated and a thickness of the metal can increases an overall thickness of the HF module. Also, the exterior of a PCB should be entirely soldered with a metal can for the purpose of electromagnetic wave shielding, and here, an overall size of the module is also increased due to the thickness of the metal can.

Another related art HF module has a structure in which an electronic component is mounted on a PCB, the entire upper surface of the PCB are molded with a molding material such that the electronic component is installed therein, and thereafter, the entire outer surface of the mold product is covered with silver (Ag)-plated film to shield electromagnetic waves. This type of HF module is thin, relative to the above-mentioned HF module, but a sufficient space is required above the electronic component to form a mold. In addition, this type of HF module has a relatively low production yield and incurs high unit cost due to the molding process and the silver (Ag) plating process.

### RELATED ART DOCUMENT

(Patent Document 1) Korean Patent Laid-Open Publication No. 10-2010-0101496

(Patent Document 2) Japanese Patent Laid-Open Publication No. 2011-198866

### SUMMARY OF THE INVENTION

An object of the present invention is to provide a high frequency (HF) module in which an airtight box using printed circuit boards (PCBs) is formed and electronic components are mounted on the bottom and ceiling of the box to considerably reduce an overall size thereof and a conductor is buried within the PCB body to obtain an electromagnetic wave shielding effect, and a manufacturing method thereof.

According to an exemplary embodiment of the present invention, there is provided a high frequency (HF) module including: a first PCB having one surface on which an electronic component is mounted; a second PCB mounted on one surface of the first PCB to form a cavity; first electronic components mounted on one surface of the first PCB within the cavity; a third PCB mounted on the other surface of the second PCB; and second electronic components mounted on one surface of the third PCB within the cavity.

The HF module may further include: an electromagnetic wave shielding unit installed within the first, second, and third PCBs, respectively, and preventing external radiation of electromagnetic waves generated by the first and second electromagnetic components.

The second electronic components may be mounted on one surface of the third PCB, and in this case, the second electronic components may be mounted at positions corresponding to first electronic components relatively low in height, among the first electronic components mounted on one surface of the first PCB.

The electromagnetic wave shielding unit installed within the first and third PCBs may be configured as a copper layer existing within the first and third PCBs.

An electromagnetic wave shielding unit installed within the second PCB may include a plurality of vias spaced apart from one another at a predetermined interval therebetween.

The vias may be configured such that a plurality of via holes are formed at predetermined intervals within the second PCB and filled with a conductive material, respectively.

The conductive material may be made of any one among gold (Au), silver (Ag), copper (Cu), aluminum (Al), or an alloy formed of a combination of two or more elements thereof.

According to another exemplary embodiment of the present invention, there is provided a method for manufacturing a high frequency (HF) module, including: a) mounting first electronic components on one surface of a first printed circuit board (PCB); b) mounting second electronic components on one surface of a third PCB; c) mounting a second PCB having a plurality of vias formed therein on one surface of the first PCB to form a cavity; and d) coupling the third PCB to the second PCB such that one surface of the first PCB with the first electronic components mounted thereon and one surface of the third PCB with the second electronic components mounted thereon face each other to thus manufacture a box-type module having an airtight internal space.

In step b), the second electronic components may be mounted on one surface of the third PCB such that the second electronic components are mounted at positions corresponding to first electronic components relatively low in height, among the first electronic components mounted on one surface of the first PCB.

In step c), the vias may be formed by forming a plurality of via holes at predetermined intervals within the second PCB and filling the plurality of via holes with a conductive material, respectively.

The via holes may be formed through dry etching using an excimer laser or a CO₂ laser.

The conductive material may be made of any one among gold (Au), silver (Ag), copper (Cu), aluminum (Al), or an alloy formed of a combination of two or more elements thereof.

In the manufacturing the box-type module having an airtight internal space in d), the box-type module may be manufactured such that upper end portions of the plurality of vias formed within the second PCB are connected to a copper layer existing within a body of the third PCB and lower end portions of the vias are connected to a copper layer existing within a body of the first PCB.

### BRIEF DESCRIPTION OF THE DRAWINGS

FIG. 1 is a vertical-sectional view illustrating a structure of a high frequency (HF) module according to an embodiment of the present invention.

FIG. 2 is a cross-sectional view illustrating a structure of the HF module according to an embodiment of the present invention.

FIG. 3 is a flow chart illustrating an execution process of a method for manufacturing an HF module according to an embodiment of the present invention.

FIGS. 4A through 4D are views sequentially illustrating a process of manufacturing an HF module according to an embodiment of the present invention.

### DESCRIPTION OF THE PREFERRED EMBODIMENTS

Hereinafter, exemplary embodiments will be described in detail with reference to the accompanying drawings so that they can be easily practiced by those skilled in the art to which the present invention pertains.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

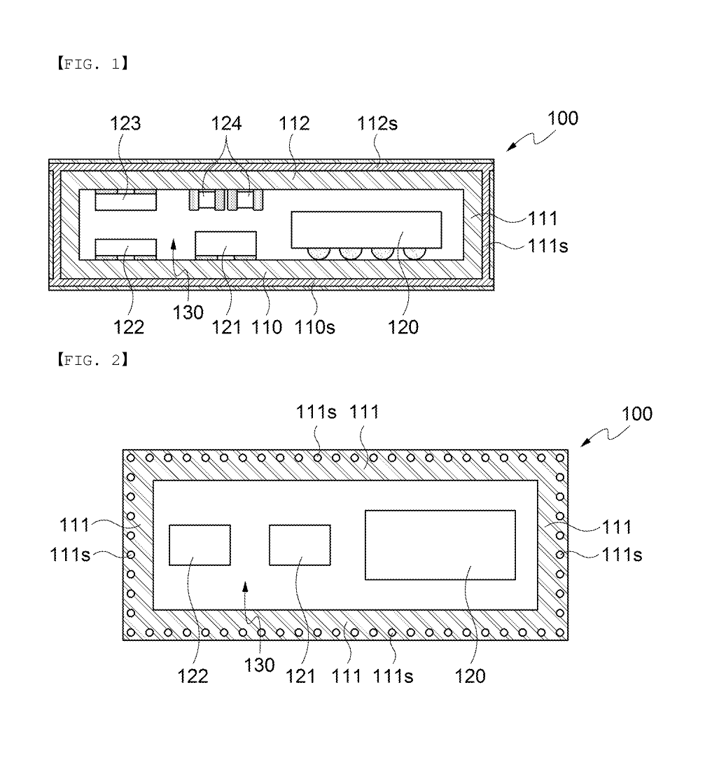

FIGS. 1 and 2 are views illustrating a structure of a high frequency (HF) module according to an embodiment of the present invention, wherein FIG. 1 is a vertical-sectional view and FIG. 2 is a cross-sectional view.

Referring to FIGS. 1 and 2, an HF module 100 according to an embodiment of the present invention includes a first PCB 110, a second PCB 111, a third PCB 112, and first and second electronic components 120 to 124. Preferably, the HF module 100 may further include electromagnetic wave shielding units 110s to 112s.

The first PCB 110 is a base of the module, and the first electronic components 120 to 122 are mounted thereon. As the first PCB 110, a PCB having a multilayer structure or a single layer structure may be used.

The second PCB 111 is mounted on one surface of the first PCB 110 to form a cavity 130. Namely, the second PCB 111 is installed as a wall surface having a predetermined height along four edges of the first PCB 110 having a quadrangular shape, forming a fence on the whole. The fence isolates the interior and the exterior, and the interior forms the single cavity 130.

The first electronic components 120 to 122 are mounted on one surface of the first PCB 110 within the cavity 130.

The third PCB 112 is mounted on the other surface of the second PCB 111. Namely, the third PCB 112 is installed as a cover above the second PCB 111 to form an airtight box together with the first PCB 110 and the second PCB 111. As the third PCB 112, a PCB having a multilayer structure or a single layer structure may also be used.

The second electronic components 123 and 124 are mounted on one surface of the third PCB 112 within the cavity 130 formed by the second PCB 111.

Here, the second electronic components 123 and 124 are mounted on a surface (i.e., a lower surface in the drawing) of the third PCB 112 facing a surface (i.e., an upper surface in the drawing) on which the electronic components 120 to 122 of the first PCB 110 are mounted, and in this case, as illustrated, the second electronic components 123 and 124 are mounted at positions corresponding to the electronic components 121 and 122 which are relatively low in height, among the first electronic components 120 to 122 mounted on the first PCB 110.

The first and second electronic components 120 to 124 are involved in signal processing for HF wireless transmission and reception. The first and second electronic components 120 to 124 may include a semiconductor chip serving as an integrated circuit (IC), a power amplifier, a low noise amplifier (LNA), a filter, and the like, or passive elements such as a resistor, a capacitor, and the like.

The electromagnetic wave shielding units 110s to 112s are installed within the first PCB 110, the third PCB 112, and the second PCB 111, respectively, and prevent electromagnetic waves generated by the first and second electronic components 120 to 124 from being radiated to the outside.

Here, as the electromagnetic wave shielding units 110s and 112s installed within the first PCB 110 and the third PCB 112, copper layers (a PCB is generally manufactured to have a copper layer buried therein) existing within the PCBs may be used.

Also, as the electromagnetic wave shielding unit 111s installed within the second PCB 111, a plurality of vias may be installed to be spaced apart from one another at a predetermined interval therebetween, as illustrated in FIG. 2.

Here, the vias may be formed such that a plurality of via holes are formed at predetermined intervals within the second PCB 111 and filled with a conductive material, respectively.

Here, as the conductive material, gold (Au), silver (Ag), copper (Cu), aluminum (Al), or an alloy formed of a combination of two or more elements thereof.

A method for manufacturing an HF module according to an embodiment of the present invention having the foregoing configuration will be described.

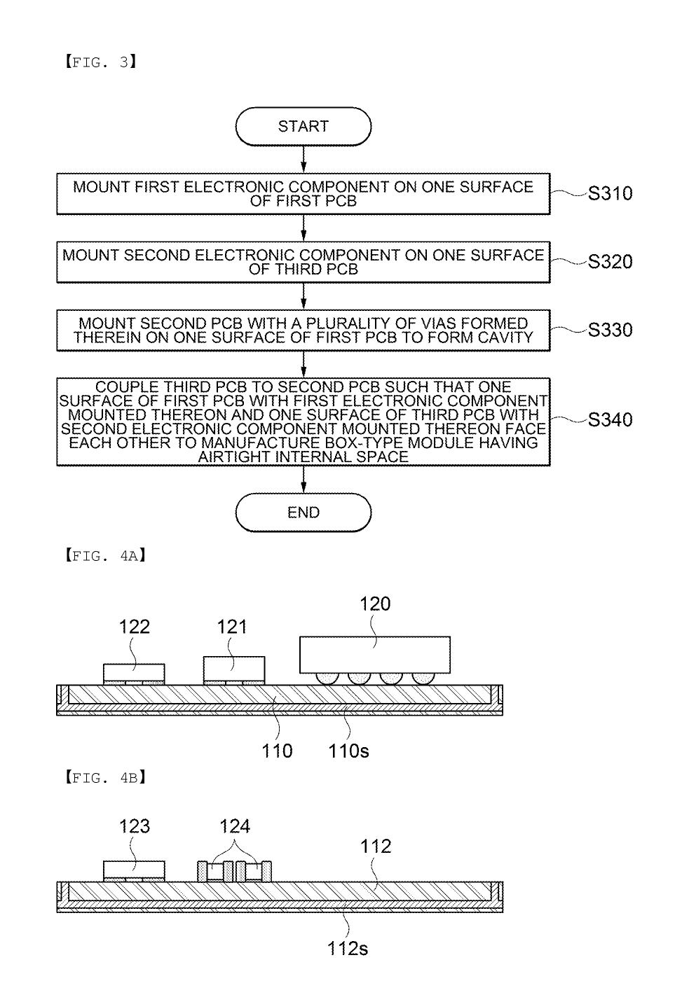

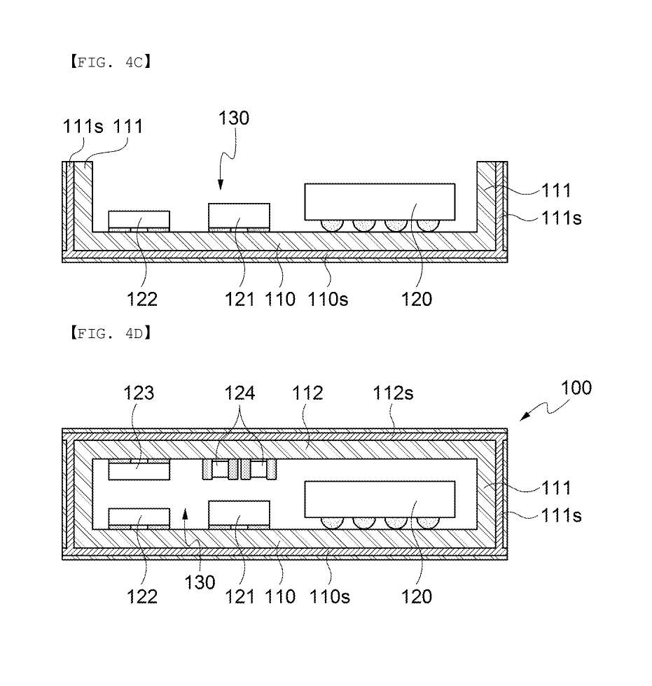

FIG. 3 is a flow chart illustrating an execution process of a method for manufacturing an HF module according to an embodiment of the present invention, and FIGS. 4A through 4D are views sequentially illustrating a process of manufacturing an HF module according to an embodiment of the present invention.

Referring to FIGS. 3 and 4A through 4D, according to the method for manufacturing an HF module, first, the first electronic components 120 to 122 are mounted at pre-set positions of one surface of the first PCB 110 (step S310, FIG. 4A).

Next, the second electronic components 123 and 124 are mounted at pre-set positions of one surface of the third PCB 112 in the same manner (step S320, FIG. 4B).

Here, in mounting the first and second electronic components 120 to 124 on the first PCB 110 and the third PCB 112, the first and second electronic components 120 to 124 may not necessarily be mounted first on the first PCB 110 and later on the third PCB 112. Namely, order thereof may be reversed or the first and second electronic components 120 to 124 may be simultaneously mounted on the first PCB 110 and the third PCB 112.

Also, in mounting the second electronic components 123 and 124 on one surface of the third PCB 112, the second electronic components 123 and 124 are mounted at positions corresponding to the first electronic components 121 and 122 relatively low in height, among the first electronic components 120 to 122 mounted on the first PCB 110. Namely, in designing the first PCB 110, positions of the first electronic components to be mounted on the first PCB 110 are determined in advance, and thus, mounting positions of the first electronic components 121 to 122 relatively low in height may be known in advance. Thus, in mounting the second electronic components 123 and 124 on the third PCB 112 installed to face the first PCB 110, the second electronic components 123 and 124 are mounted at positions corresponding to mounting positions of the first electronic components 121 and 122 relatively low in height. Accordingly, an overall height may be significantly reduced in completing the HF module product.

When mounting of the first and second electronic components 120 to 124 on the first PCB 110 and the third PCB 112 is completed, the second PCB 111 having a predetermined height and including a plurality of vias formed therein is mounted on one surface of the first PCB 110 to form the cavity 130 (step S330, FIG. 4C). Namely, as mentioned above with reference to FIG. 2, the second PCB 111 is installed along the four sides of the first PCB 110 to form a fence.

Here, the vias formed within the second PCB 111 may be formed by forming a plurality of via holes within the second PCB 111 such that they are spaced apart from one another at a predetermined interval therebetween, and filled with a conductive material, respectively.

In this case, in order to form the via holes, dry etching using an excimer laser or CO₂ laser may be used. Also, as the conductive material, gold (Au), silver (Au), copper (Cu), aluminum (Al), or an ally made of a combination of two or more elements thereof may be used.

In this manner, when the formation of the cavity 130 is completed as the second PCB 111 is mounted on the first PCB 110, the third PCB 112 is coupled to the second PCB 111 such that one surface of the third PCB 112 with the second electronic components 123 and 124 mounted thereon and one surface of the first PCB 110 with the first electronic components 120 to 122 mounted thereon face each other, thus manufacturing a box-type module having an airtight internal space (step S340, FIG. 4D). Namely, the third PCB 112 is reversed such that the second electronic components 123 and 124 mounted thereon face downwardly, and coupled to the upper end portion of the second PCB 111. In this case, of course, the third PCB 112 is coupled to the second PCB 111 such that the second electronic components 123 and 124 mounted on the third PCB 112 correspond to the electronic components 121 and 122 mounted to be relatively low in height on the first PCB 110. As the third PCB 112 is coupled to the second PCB 111, the single box-type HF module 110 having an airtight internal space is completely manufactured.

Here, in manufacturing the box-type module 100 having an airtight internal space as described above, the box-type module 110 is manufactured such that upper end portions of the plurality of vias as the electromagnetic wave shielding unit 111s formed within the second PCB 111 are connected to the copper layer (i.e., the electromagnetic wave shielding unit 112s of the third PCB 112) existing within the body of the third PCB 112, and lower end portions of the vias are connected to the copper layer (i.e., the electromagnetic wave shielding unit 110s of the first PCB 110) existing within the body of the first PCB 110. Accordingly, the shield may be designed without having to use a shield material.

As described above, in the case of the HF module and the manufacturing method thereof according to embodiments of the present invention, since electronic components, which are generally installed on a two-dimensional (2d) plane of an existing PCB, are installed on the first PCB and the third PCB having a three-dimensional (3D) structure, respectively, whereby an overall size of the module product can be further reduced, and since the copper layer within the PCB is used as an electromagnetic wave shielding unit, the shield can be designed without using an additional shield material.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A high frequency (HF) module comprising:
a first PCB having one surface on which an electronic component is mounted;
a second PCB mounted on one surface of the first PCB to form a cavity;
first electronic components mounted on one surface of the first PCB within the cavity;
a third PCB mounted on the other surface of the second PCB; and
second electronic components mounted on one surface of the third PCB within the cavity.

2. The HF module according to claim 1, further comprising:
an electromagnetic wave shielding unit installed within the first, second, and third PCBs, respectively, and preventing external radiation of electromagnetic waves generated by the first and second electromagnetic components.

3. The HF module according to claim 1, wherein the second electronic components are mounted on one surface of the third PCB such that the second electronic components are mounted at positions corresponding to first electronic components relatively low in height, among the first electronic components mounted on one surface of the first PCB.

4. The HF module according to claim 2, wherein the electromagnetic wave shielding unit installed within the first and third PCBs is configured as a copper layer existing within the first and third PCBs.

5. The HF module according to claim 2, wherein an electromagnetic wave shielding unit installed within the second PCB includes a plurality of vias spaced apart from one another at a predetermined interval therebetween.

6. The HF module according to claim 5, wherein the vias are configured such that a plurality of via holes are formed at predetermined intervals within the second PCB and filled with a conductive material, respectively.

7. The HF module according to claim 6, wherein the conductive material is made of any one among gold (Au), silver (Ag), copper (Cu), aluminum (Al), or an alloy formed of a combination of two or more elements thereof.

8. A method for manufacturing a high frequency (HF) module, the method comprising:
mounting first electronic components on one surface of a first printed circuit board (PCB);
mounting second electronic components on one surface of a third PCB;
mounting a second PCB having a plurality of vias formed therein on one surface of the first PCB to form a cavity; and
coupling the third PCB to the second PCB such that one surface of the first PCB with the first electronic components mounted thereon and one surface of the third PCB with the second electronic components mounted thereon face each other to thus manufacture a box-type module having an airtight internal space.

9. The method according to claim 8, wherein, in the mounting second electronic components, the second electronic components are mounted on one surface of the third PCB such that the second electronic components are mounted at positions corresponding to first electronic components relatively low in height, among the first electronic components mounted on one surface of the first PCB.

10. The method according to claim 8, wherein, in the mounting a second PCB, the vias are formed by forming a plurality of via holes at predetermined intervals within the second PCB and filling the plurality of via holes with a conductive material, respectively.

11. The method according to claim 10, wherein the via holes are formed through dry etching using an excimer laser or a CO₂ laser.

12. The method according to claim 10, wherein the conductive material is made of any one among gold (Au), silver (Ag), copper (Cu), aluminum (Al), or an alloy formed of a combination of two or more elements thereof.

13. The method according to claim 8, wherein, in the manufacturing the box-type module having an airtight internal space in the coupling the third PCB to the second PCB, the box-type module is manufactured such that upper end portions of the plurality of vias formed within the second PCB are connected to a copper layer existing within a body of the third PCB and lower end portions of the vias are connected to a copper layer existing within a body of the first PCB.
